(19) United States
(12) Patent Application Publication
(10) Pub. No.: US 2024/0243238 A1
(43) Pub. Date: Jul. 18, 2024

(54) OPTOELECTRONIC SEMICONDUCTOR DEVICE

(71) Applicant: UNIKORN SEMICONDUCTOR CORPORATION, Hsinchu (TW)

(72) Inventors: Ya-Nan Lin, Hsinchu (TW); Shih-I Chen, Hsinchu (TW); Chun-Ming Wu, Hsinchu (TW); Chin-I Lin, Hsinchu (TW); Chun-Ru Yang, Hsinchu (TW)

(21) Appl. No.: 18/413,523

(22) Filed: Jan. 16, 2024

(30) Foreign Application Priority Data
Jan. 17, 2023 (TW) 112102028

(51) Int. Cl. H01L 33/60; H01L 33/62

(52) U.S. Cl. CPC H01L 33/60; H01L 33/62

(57) ABSTRACT

An optoelectronic semiconductor device is provided. The optoelectronic semiconductor device includes a substrate, a semiconductor stack located on the substrate; a first trench and a second trench provided in the semiconductor stack; a first insulating layer filling in the first trench and covering the semiconductor stack; a first metal layer covering the first insulating layer; a second metal layer covering the first insulating layer; and a second insulating layer located between the first metal layer and the first insulating layer, and between the second metal layer and the first insulating layer. A part of the second trench is uncovered by the first insulating layer and the second insulating layer.

### CROSS-REFERENCE TO RELATED APPLICATIONS

The present application claims priority of Taiwan Application No. 112102028, filed on Jan. 17, 2023, which is incorporated by reference herein in its entirety.

### BACKGROUND

### Technical Field

The present disclosure relates to optoelectronics semiconductor device, and more particularly to the optoelectronic semiconductor device with an insulating layer between a flat layer and an electrode.

### Description of the Related Art

Semiconductor components are widely used, and the research and development of related materials is also continuously being carried out. For example, III-V semiconductor materials containing group III and group V elements may be applied to various optoelectronic semiconductor components, such as light-emitting components (for example, light-emitting diodes or laser diodes), light-absorbing components (for example, photodetectors or solar cells) or non-luminous components (for example, power components of switches or rectifiers), which can be used in lighting, medical treatment, display, communication, sensing, power supply systems and other applications. With the development of technology, the need for development is still required for optoelectronic semiconductor devices. Although existing optoelectronic semiconductor devices have generally met requirements, they are not satisfactory in all respects, and further improvements are still needed.

### SUMMARY

Some embodiments of the present disclosure provide an optoelectronic semiconductor device. The optoelectronic semiconductor device includes a substrate, a semiconductor stack located on the substrate; a first trench and a second trench provided in the semiconductor stack; a first insulating layer filling in the first trench and covering the semiconductor stack; a first metal layer covering the first insulating layer; a second metal layer covering the first insulating layer; and a second insulating layer located between the first metal layer and the first insulating layer, and between the second metal layer and the first insulating layer. A part of the second trench is uncovered by the first insulating layer and the second insulating layer.

### BRIEF DESCRIPTION OF THE DRAWINGS

Embodiments of the present disclosure can be best understood from the following detailed description in conjunction with the accompanying drawings. It should be noted that, in accordance with the common practice in the industry, various features are not drawn to scale. In fact, the dimensions of the various elements may be arbitrarily increased or reduced to clearly illustrate the features of the embodiments of the present disclosure.

FIG. 1 illustrates a top view of an optoelectronic semiconductor device according to some embodiments of the present disclosure.

FIG. 2 illustrate cross-sectional view of the optoelectronic semiconductor device along line A-A′ shown in FIG. 1 according to some embodiments of the present disclosure.

FIGS. 3A-3D illustrate cross-sectional views of works in process during manufacturing an optoelectronic semiconductor device according to some embodiments of the present disclosure.

### DETAILED DESCRIPTION

The following disclosure provides many different embodiments, or examples, for implementing different features of the described subject matter. Specific examples of elements and arrangements are described below to simplify the present description. These are, of course, merely examples and are not intended to be limiting. For example, dimensions of elements are not limited to the disclosed ranges or values, but may depend on process conditions and/or desired characteristics of devices. Further. the formation of a first feature over or on a second feature in the description that follows may include embodiments in which the first and second features are formed in direct contact, and may also include embodiments in which additional features may be formed between the first and second features, such that the first and second features may not be in direct contact.

It should be understood that, the extra steps can be implemented before, between or after the mentioned method. Some steps can be replaced or omitted according to some embodiments of the disclosure.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 45 degrees or at other orientations) and the spatially relative descriptors used herein may likewise be interpreted accordingly.

It should be understood that, although the use of the terms such as “first”, “second”, “third” to describe different elements, parts, areas, layers and/or sections, the actual elements, parts, areas, layers and/or sections should not be limited by the terms. The purpose of using the terms is only for distinguish one element, part, area, layer and/or section from the other. Therefore, the first element, part, area, layer and/or section discussed below can also be named as the second elements, part, area, layer and/or section, without deviating from the present disclosure.

All the terms including the technical terms and the scientific terms used in this disclosure can be identified by the person having the ordinary skill in the art. It should be noted that, the terms, which is defined by the universal dictionary, should be identified as the meaning consistent with the background and contextually consistent. Unless the terms have special definitions in the embodiment of the present disclosure, the terms should not be interpreted by an ideal way or overly formal way.

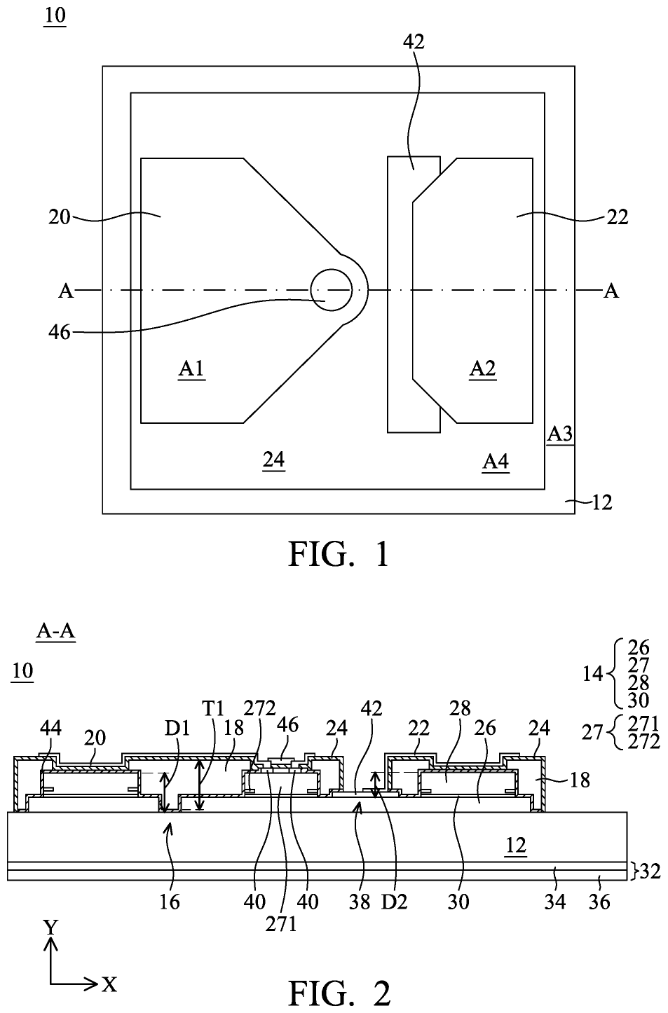

FIGS. 1-2 show optoelectronics semiconductor device 10 according to embodiments of the present disclosure. FIG. 1 illustrates a top view of an optoelectronic semiconductor device 10. FIG. 2 illustrate cross-sectional view of the optoelectronic semiconductor device 10 along line A-A′ shown in FIG. 1.

In FIGS. 1-2, the optoelectronics semiconductor device 10 includes a substrate 12, a semiconductor stack 14, a first trench 16, a first insulating layer 18, a first metal layer 20, a second metal layer 22 and a second insulating layer 24. The semiconductor stack 14 locates on the substrate 12, and the first trench 16 is formed in the semiconductor stack 14 and further penetrates across the semiconductor stack 14 to reach the substrate 12. The first insulating layer 18 fills the first trench 16 and covers the semiconductor stack 14. The first metal layer 20 covers the first insulating layer 18. The second metal layer 22 covers the first insulating layer 18. The second insulating layer 24 locates between the first metal layer 20 and the first insulating layer 18 and between the second metal layer 22 and the first insulating layer 18.

In some embodiments, the substrate 12 can include semiconductor material, ceramic material, glass, polymer, or the combination thereof. In some embodiments, the semiconductor material includes semiconductor element (such as silicon and/or germanium), compound semiconductor (such as gallium nitride (GaN), silicon carbide (SiC), gallium arsenide (GaAs), gallium phosphide (GaP), indium phosphide (InP), indium arsenide (InAs), gallium antimonide (GaSb), indium antimonide (InSb), LiTaO₃ and/or LiNbO₃), or alloy semiconductor (such as Si—Ge alloy, P—As—Ga alloy, As—Al—In alloy, As—Al—Ga alloy, P—Ga—In alloy, and/or As—P—Ga—In alloy), or the combination thereof.

In some embodiments, the substrate 12 can be composite substrate, such as thin-film transistor (TFT), complementary metal-oxide-semiconductor (CMOS), driving element, or the combination thereof. The extra elements can provide electrical connection to the elements located above the substrate 12.

As shown in FIG. 2, the semiconductor stack 14 includes a first semiconductor structure 26, a second semiconductor structure 28 on the first semiconductor structure 26, and an active structure 30 between the first semiconductor structure 26 and the second semiconductor structure 28. The semiconductor stack 14 further includes a current confine layer 27 having a first region 271 and a second region 272 surrounding the first region 271. The current confine layer 27 can locate in the first semiconductor structure 26 or in the second semiconductor structure 28. In some embodiments, the current confine layer 27 locates between the first semiconductor structure 26 and the active structure 30. In other embodiment, the current confine layer 27 locates between the second semiconductor structure 28 and the active structure 30. The current can be blocked in the second region 272, and therefore the current can be confined and led to the first region 271.

In some embodiments, the first semiconductor structure 26 can include n-type semiconductor material, such as n-type group III-V semiconductor material. In some embodiments, the n-type group III-V semiconductor material can include binary, trinary or quaternary III-V semiconductor material with n-type dopant. In some embodiments, the n-type dopant includes but is not limited to Si, Te or O. In some embodiments, binary III-V semiconductor material includes but is not limited to GaN, GaAs or InP. In some embodiments, trinary III-V semiconductor material includes but is not limited to AlInN, InGaN, AlGaN, AlGaAs, InGaAs or InGaP. In some embodiments, quaternary III-V semiconductor material includes but is not limited to InAlGaN. In one embodiment of the disclosure, the first semiconductor structure 26 can be n-type distributed Bragg reflector (DBR).

In some embodiments, the second semiconductor structure 28 can include p-type semiconductor material, such as p-type group III-V semiconductor material. In some embodiments, the p-type group III-V semiconductor material can include binary, trinary or quaternary III-V semiconductor material with p-type dopant. In some embodiments, the p-type dopant includes but is not limited to Be, Mg, C, Ca or Sr. In some embodiments, binary III-V semiconductor material includes but is not limited to be GaN, GaAs or InP. In some embodiments, trinary III-V semiconductor material includes but is not limited to AlInN, InGaN, AlGaN, AlGaAs, InGaAs or InGaP. In some embodiments, quaternary III-V semiconductor material includes but is not limited to InAlGaN. In one embodiment of the disclosure, the second semiconductor structure 28 can be p-type distributed Bragg reflector (DBR).

In some embodiments, the active structure 30 can include multiple-quantum well (MQW) composed by alternately stacking of one or multiple barrier layer(s) and one or multiple well layer(s). The barrier layer includes GaN, AlGaN, AlGaAs, GaAs, GaInP or GaInAsP. The well layer includes GaN, InGaN, AlGaN, AlGaAs, GaAs, InGaAs, GaAsP, AlGaInP, GaInP or GaInAsP.

As shown in FIG. 2, the first trench 16 penetrates the semiconductor stack 14 to reach the substrate 12. The first insulating layer 18 fills in and fills up the first trench 16 to achieve planarization. In the embodiment, along the vertical direction (such as Y direction), the first insulating layer 18 has a maximum thickness T1 and the first trench 16 has a first depth D1. The maximum thickness T1 is larger than or equal to the first depth D1. In some embodiments, the first insulating layer 18 can include organic insulating material. In some embodiments, the organic insulating material can include polyimide (PI), benzocyclobutene (BCB) or the combination thereof.

In FIG. 2, the first metal layer 20 separates from the second metal layer 22. The first metal layer 20 and the second metal layer 22 locate on the same side of the substrate 12. That is, the first metal layer 20 does not overlap with the second metal layer 22 along the vertical direction. The first metal layer 20 and the second metal layer 212 electrically connect to the semiconductor stack 14. More specifically, the first metal layer 20 electrically connects to the second semiconductor structure 28 of the semiconductor stack 14, and the second metal layer 22 electrically connects to the first semiconductor structure 26 of the semiconductor stack 14. In some embodiment, the first metal layer 20 and the second metal layer 22 can include Mo, Al, Cu, Ti, Au, Pt, Cr or the combination thereof, such as Ti/Au, Ti/Pt/Au or Cr/Au. The first metal layer 20 and the second metal layer 22 can serve as electrodes to connect to outside circuit.

The second insulating layer 24 covers and surrounds the first insulating layer 18. More specifically, the first insulating layer 18 includes a top surface and a side surface, and the second insulating layer 24 covers the top surface and the side surface. The first trench 16 is devoid of the second insulating layer 24 since the first insulating layer 18 fills up the first trench 16. In some embodiments, the second insulating layer 24 can include inorganic insulating material. In some embodiments, the inorganic insulating material can be oxide (such as silicon oxide (SiOₓ), alumina oxide (AlOₓ)), nitride (such as silicon nitride (SiNₓ)), oxynitride (such as silicon oxynitride (SiOₓN_{y})), or the combination thereof. In some embodiments, the second insulating layer 24 and the first insulating layer 18 include different materials.

As shown in FIG. 2, the optoelectronics semiconductor device 10 further includes a light-guiding structure 32. The light guiding structure 32 and the semiconductor stack 14 respectively locate on the opposite sides of the substrate 12. That is, the substrate 12 locates between the semiconductor stack 14 and the light-guiding layer 32. The light-guiding layer 32 includes a plurality of light-guiding layers with different refractive indexes. The brightness can be enhanced through the variation of refractive indexes of the light-guiding structure 32. For example, the light-guiding structure 32 includes two light-guiding layers, such as first light-guiding layer 34 and a second light-guiding layer 36, with different refractive indexes. The substrate 12 includes a first side and a second side opposite to the first side, and the semiconductor stack 14 locates on the first side of the substrate 12. The first guiding layer 34 locates on the second side of the substrate 12, and the second light-guiding layer 36 locates on the first light-guiding layer 34 as shown in FIG. 2. In some embodiments, the first light-guiding layer 34 close to the substrate 12 has a refractive index higher than that of the second light-guiding layer 36 away from the substrate 12. In some embodiments, the firs light-guiding layer 34 and the second light-guiding layer 36 can include titanium oxide (TiOₓ) or silicon oxide (SiOₓ). In some embodiments, the first insulating layer 34 can include titanium oxide, and the second insulating layer 36 can include silicon oxide.

The optoelectronic semiconductor device 10 optionally includes a second trench 38 in the semiconductor stack 14 that reaches the first semiconductor structure 26. The optoelectronic semiconductor device 10 optionally includes a first contact layer 40 on the second semiconductor structure 28 and a second contact layer 42 in the second trench 38. That is, the second contact layer 42 locates on the first semiconductor structure 26 exposed by the second trench 38. In the embodiment, the first insulating layer 18 fills in the second trench 38 and covers a part of the second contact layer 42. A part of the second trench 38 is uncovered by the first insulating layer 18 and the second insulating layer 24. In the embodiment, the first trench 16 includes the first depth D1 and the second trench 38 includes a second depth D2 different from the first depth D1. More specifically, the first depth D1 is larger than the second depth D2. The first depth D1 and the second depth D2 are perpendicular to a stacking direction of the first semiconductor structure 26, the active structure 30 and the second semiconductor structure 28, and are parallel to Y direction shown in FIG. 2.

In some embodiments, the first contact layer 40 and the second contact layer 42 can include metal oxide material, metal or alloy. The metal oxide material includes indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). The metal may include germanium (Ge), beryllium (Be), zinc (Zn), gold (Au), platinum (Pt), titanium (Ti), aluminum (Al), nickel (Ni), or copper (Cu). The alloy may include at least two metals, such as gold-tin (AuSn), tin-silver-copper (SnAgCu), germanium-gold-nickel (GeAuNi), beryllium-gold (BeAu), germanium-gold (GeAu) or zinc gold (ZnAu). The first metal layer 20 electrically connects to the second semiconductor structure 28 of the semiconductor stack 14 through the first contact layer 40. The second metal layer 22 electrically connects to the first semiconductor structure 26 of the semiconductor stack 14 through the second contact layer 42. The second metal layer 22 partially covers the second contact layer 42.

As shown in FIG. 2, the optoelectronic semiconductor device 10 optionally includes a third insulating layer 44 between the semiconductor stack 14 and the first insulating layer 18. The third insulating layer 44 partially contacts the second insulating layer 24 and partially covers the second contact layer 42. In some embodiments, the third insulating layer 44 can include the inorganic insulating material, and the inorganic insulating material can be oxide (such as silicon oxide (SiOₓ), aluminium oxide (AlOₓ)), nitride (such as silicon nitride (SiNₓ)), oxynitride (such as silicon oxynitride (SiOₓN_{y})), or the combination thereof.

In some embodiments, the third insulating layer 44 and the second insulating layer 24 include the same material or different materials. In one embodiment, the third insulating layer 44 and the second insulating layer 24 include SiNₓ.

The optoelectronic semiconductor device 10 optionally includes reflective layer 46 on the first metal layer 20. In some embodiments, the reflective layer 46 can serve as a mirror to reflect lights, and thus the light extraction efficiency can be enhanced. The reflective layer 46 overlaps the first region 271. In some embodiments, the reflective layer 46 electrically connects to the second semiconductor structure 28 of the semiconductor stack 14 through the first metal layer 20. In one embodiment, the reflective layer 46 is insulated and does not electrically connect to the first metal layer 20. In some embodiments, a projection of the reflective layer 46 to the substrate 12 in a vertical direction locates within a projection of the first metal layer 20 to the substrate 12 in a vertical direction. The projection of the reflective layer 46 to the substrate 12 in a vertical direction overlaps with a projection of the active structure 30 to the substrate 12 in a vertical direction. In some embodiments, the reflective layer 46 passes through the first metal layer 20 and contacts the second insulating layer 24. In some embodiments, the reflective layer 46 can include metal reflective materials, such as Al, Ag, Au or Cu, distributed Bragg reflector (DBR) or the combination thereof. The first metal layer 20, the second metal layer 22, the reflective layer 46, the first contact layer 40 and the second contact layer 42 locate on the same side of the semiconductor stack 14 as shown in FIG. 2.

As shown in FIGS. 1-2, the first metal layer 20 and the second metal layer 22 on the same side of the substrate 12, and a projection of the first metal layer 20 to the substrate 12 dose not overlap with a projection of the second metal layer 22 to the substrate 12. The first metal layer 20 separates the second metal layer 22. The second metal layer 22 covers a portion of the second contact layer 42, and another portion of the second contact layer 42 without being covered by the second metal layer 22 can be covered by the second insulating layer 24. In other embodiment, the second metal layer 22 can fully cover the second contact layer 42. In one embodiment, from a top view of the optoelectronic semiconductor device 10, the first metal layer 20 has a first area A1, the second metal layer 22 has a second area A2, and the substrate 12 has a third area A3. A first ratio of a sum of the first area A1 and the second area A2 to the third area A3 is between 0.2 and 0.95, such as 0.4, 0.6, 0.8. In one embodiment, from a top view of the optoelectronic semiconductor device 10, the second insulating layer 24 has a fourth area A4, and a second ratio of the sum of the first area A1 and the second area A2 to the fourth area A4 is between 0.5 and 1. In some embodiments, from a top view of the optoelectronics semiconductor device 10, the first insulating layer 18 includes an insulating area (not shown), and a third ratio of the insulating area to the third area A3 is between 0.6 and 0.8.

In the disclosure, the shapes of the first metal layer 20, the second metal layer 22, the reflective layer 46 and the second contact layer 42 from the top op view of the optoelectronic semiconductor device 10 are not limited. The shapes can be circle, rectangle, trapezoid, other polygon, or combination thereof.

In the present disclosure, the optoelectronic semiconductor device 10 can be vertical cavity surface emitting laser (VCSEL).

The first insulating layer 18 in the optoelectronic semiconductor device 10 can serve as a flat layer to planarize the concaves and convex, and facilitates the formations of the first metal layer 20 and the second metal layer 22. Therefore, the height difference in the optoelectronic semiconductor device 10 can be eliminated, and the risk of breakage of the first metal layer 20 and the second metal layer 22 caused by height difference can be further decreased. Besides, the second insulating layer 24 between the first insulating layer 18 and the first metal layer 20 (and/or second metal layer 22) can enhance the adhesive ability between the metal layers 20, 22 and the first insulating layer 18. Therefore, the problem of poor adhesion between the metal layers 20, 22 and the first insulating layer 18 caused by large contacting area can be solved. In the disclosure, the problem of poor adhesion between the metal layers 20, 22 and the first insulating layer 18 can also be effectively solved by the specific values of the first ratio, the second ratio and/or the third ratio.

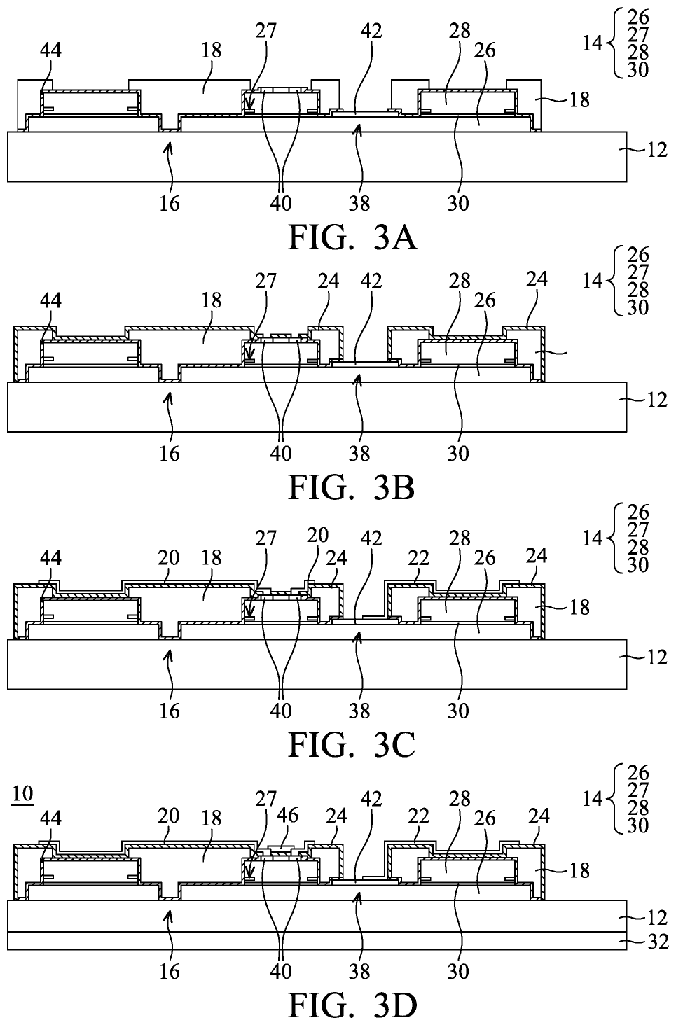

FIGS. 3A-3D show cross-sectional views of works in process during manufacturing an optoelectronic semiconductor device, according to some embodiments of the present disclosure.

In FIG. 3A, the substrate 12 is provided, and the semiconductor stack 14, the first contact layer 40 and the second contact layer 42 are formed on the substrate 12. The first trench 16 and the second trench 38 are formed in the semiconductor stack 14. The semiconductor stack 14 sequentially includes the first semiconductor structure 26, the active structure 30 and a second semiconductor structure 28 from bottom to top. The first insulating layer 18 (such as organic insulating material) fills in the first trench 16 and the second trench 38 and covers the semiconductor stack 14. The first contact layer 40 and the second contact layer 42 are uncovered by the first insulating layer 18. Before forming the first insulating layer 18, the third insulating layer 44 firstly covers the semiconductor stack 14, the first contact layer 40 and the second contact layer 42, and therefore the third insulating layer 44 locates between the first insulating layer 18 and the semiconductor stack 14. The first contact layer 40 and a portion of the second contact layer 42 are uncovered by the third insulating layer 44.

In some embodiments, the first insulating layer 18 can be formed by evaporation, spin-coating, low-pressure chemical vapor deposition (LPCVD), low-temperature chemical vapor deposition (LTCVD), rapid thermal chemical vapor deposition (RTCVD), plasma enhanced chemical vapor deposition (PECVD), atomic layer deposition (ALD), physical vapor deposition (PVD) and combination thereof. In some embodiments, a curing process can be implanted after forming the first insulating layer 18, in order to stabilize and/or fix the first insulating layer 18 in the first trench 16 and the second trench 38.

As shown in FIG. 3B, forming the second insulating layer 24 to cover and surround the first insulating layer 18. The first contact layer 40 and the second contact layer 42 are uncovered by the second insulating layer 24.

In some embodiments, the second insulating layer 24 can be formed by sputter deposition, evaporation, spin-coating, low-pressure chemical vapor deposition (LPCVD), low-temperature chemical vapor deposition (LTCVD), rapid thermal chemical vapor deposition (RTCVD), plasma enhanced chemical vapor deposition (PECVD), atomic layer deposition (ALD), physical vapor deposition (PVD), molecular beam epitaxy (MBE) or combination thereof.

As shown in FIG. 3C, forming the first metal layer 20 to cover the second insulating layer 24 and the first contact layer 40. The first metal layer 20 electrically connects to the second semiconductor structure 28 of the semiconductor stack 14 through the first contact layer 40. At the same time, forming the second metal layer 22 to cover the second insulating layer 24 and the second contact layer 42. The second metal layer 22 electrically connects to the first semiconductor structure 26 of the semiconductor stack 14 through the second contact layer 42.

In some embodiments, the first metal layer 20 and the second metal layer 22 can be formed by electrical deposition, sputter deposition, evaporation, chemical vapor deposition (CVD), atomic layer deposition (ALD), physical vapor deposition (PVD), molecular beam epitaxy (MBE) or combination thereof.

As shown in FIG. 3D, forming the reflective layer 46 on the second insulating layer 24. The reflective layer 46 electrically connects to the first metal layer 20. After that, the light-guiding structure 32, which including the plurality of light-guiding layers with different refractive indexes, is formed on the second side of the substrate 12.

In some embodiments, the refractive layer 46 can be formed by electrical deposition, sputter deposition, evaporation, chemical vapor deposition (CVD), atomic layer deposition (ALD), physical vapor deposition (PVD), molecular beam epitaxy (MBE) or combination thereof.

The foregoing has outlined features of several embodiments such that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An optoelectronic semiconductor device, comprising:
a substrate;
a semiconductor stack located on the substrate;
a first trench and a second trench provided in the semiconductor stack;
a first insulating layer filling in the first trench and covering the semiconductor stack;
a first metal layer covering the first insulating layer;
a second metal layer covering the first insulating layer; and
a second insulating layer located between the first metal layer and the first insulating layer, and between the second metal layer and the first insulating layer;
wherein a part of the second trench is uncovered by the first insulating layer and the second insulating layer.

2. The optoelectronic semiconductor device of claim 1, wherein the first insulating layer fills up the first trench.

3. The optoelectronic semiconductor device of claim 1, further comprising a light-guiding structure, and the light-guiding layer and the semiconductor stack respectively locate on opposite sides of the substrate.

4. The optoelectronic semiconductor device of claim 1, wherein the first metal layer comprises a first area, the second metal layer comprises a second area, and the substrate comprises a third area from a top view of the optoelectronic semiconductor device, and a first ratio of a sum of the first area and the second area to the third area is between 0.2 and 0.95.

5. The optoelectronic semiconductor device of claim 1, wherein the semiconductor stack comprises a first semiconductor structure, a second semiconductor structure and an active structure between the first semiconductor structure and the second semiconductor structure, and the second trench is provided in the semiconductor stack to reach the first semiconductor structure.

6. The optoelectronic semiconductor device of claim 5, further comprising a contact layer located on the first semiconductor structure which is exposed by the second trench.

7. The optoelectronic semiconductor device of claim 1, wherein the first trench comprises a first depth different from a second depth of the second trench.

8. The optoelectronic semiconductor device of claim 1, wherein the second insulating layer covers and surrounds the first insulating layer.

9. The optoelectronic semiconductor device of claim 1, wherein there is devoid of the second insulating layer in the first trench.

10. The optoelectronic semiconductor device of claim 1, wherein the first insulating layer comprises a material different from that of the second insulating layer.

11. The optoelectronic semiconductor device of claim 1, further comprising a third insulating layer between the semiconductor stack and the first insulating layer.

12. The optoelectronic semiconductor device of claim 11, wherein the first insulating layer locates between the second insulating layer and the third insulating layer.

13. The optoelectronic semiconductor device of claim 11, wherein the third insulating layer contacts the second insulating layer.

14. The optoelectronic semiconductor device of claim 11, wherein the third insulating layer and the second insulating layer comprise the same material.

15. The optoelectronic semiconductor device of claim 1, further comprising a reflective layer locates on the semiconductor stack.

16. The optoelectronic semiconductor device of claim 15, wherein the reflective layer electrically connects to the first metal layer.

17. The optoelectronic semiconductor device of claim 15, wherein the reflective layer contacts the second insulating layer.

18. The optoelectronic semiconductor device of claim 15, wherein the semiconductor stack further comprises a current confine layer having a first region and a second region surrounding the first region, wherein the reflective layer overlapped the first region.

19. The optoelectronic semiconductor device of claim 1, wherein the first trench comprises a first depth and the first insulating layer comprises a maximum thickness larger than or equal to the first depth.

20. The optoelectronic semiconductor device of claim 1, wherein the first metal layer comprises a first area, the second metal layer comprises a second area, and the second insulating layer comprises a fourth area from a top view of the optoelectronic semiconductor device, and a second ratio of a sum of the first area and the second area to the fourth area is between 0.5 and 1.
